(19) United States
(12) Patent Application Publication
(10) Pub. No.: US 2026/0006917 A1
(43) Pub. Date: Jan. 1, 2026

(54) ELECTRONIC DEVICE

(71) Applicant: InnoLux Corporation, Miao-Li County (TW)

(72) Inventors: Wen-Tsai HSU, Miao-Li County (TW); Chung-Cheng LIAO, Miao-Li County (TW)

(21) Appl. No.: 19/219,298

(22) Filed: May 27, 2025

(30) Foreign Application Priority Data
Jun. 26, 2024 (CN) 202410837536.2

(51) Int. Cl. H10D 86/40; H10D 86/60

(52) U.S. Cl. CPC H10D 86/471; H10D 86/441; H10D 86/60

(57) ABSTRACT

An electronic device includes a substrate and a first switching element. The substrate has a peripheral circuit area. The first switching element is disposed in the peripheral circuit area and includes a first transistor and a second transistor. A first gate of the first transistor is connected to a second gate of the second transistor. A projection area of a semiconductor layer of the first transistor and a semiconductor layer of the second transistor to the substrate is within a projection area of the first gate and the second gate to the substrate.

### CROSS-REFERENCE TO RELATED APPLICATIONS

This application claims the benefits of the Chinese Patent Application Serial Number 202410837536.2, filed on Jun. 26, 2024, the subject matter of which is incorporated herein by reference.

### BACKGROUND

### Field of the Disclosure

The present disclosure relates to an electronic device and, more particularly, to an electronic device having a switching element with a dual-gate structure.

### Description of Related Art

As the resolution and/or operating frequency of products (for example, touch electronic devices) continues to increase, the charging rate of the pixels of the electronic device becomes more and more stringent. The current amount of the transistor element when turned on is usually increased by increasing the operating voltage, so as to meet charging requirements

However, under high voltage operation, the leakage current of the transistor when turned off also increases, which affects the voltage of the node. When the leakage current becomes larger, it will be difficult to maintain the voltage of the gate of the transistor connected to the node at the required level, causing the panel to be unable to operate properly.

Therefore, it is desired to provide an improved electronic device so as to mitigate and/or obviate the aforementioned problems.

### SUMMARY

The present disclosure provides an electronic device, which includes: a substrate having a peripheral circuit area; and a first switching element disposed in the peripheral circuit area and provided with a first transistor and a second transistor, wherein a first gate of the first transistor is connected to a second gate of the second transistor, wherein a projection range of a semiconductor layer of the first transistor and a semiconductor layer of the second transistor to the substrate is within a projection range of the first gate electrode and the second gate electrode to the substrate.

The present disclosure further provides an electronic device, which includes: a substrate having a peripheral circuit area; and a first switching element disposed in the peripheral circuit area and provided with a first transistor and a second transistor, wherein a first gate of the first transistor is connected to a second gate of the second transistor, and wherein, in a top view direction of the electronic device, a gate pattern formed by the first gate and the second gate includes at least one opening, and the at least one opening does not overlap a semiconductor layer of the first transistor and a semiconductor layer of the second transistor.

The present disclosure further provides an electronic device, which includes: a substrate having a peripheral circuit area; and a first switching element disposed in the peripheral circuit area and provided with a first transistor and a second transistor, wherein a first gate of the first transistor is connected to a second gate of the second transistor; a second switching element disposed in the peripheral circuit area and provided with a third transistor and a fourth transistor, wherein a third gate of the third transistor is connected to a fourth gate of the fourth transistor, wherein a first end of the first switching element and a first end of the second switching element are connected to a node, a projection range of a semiconductor layer of the first transistor and a semiconductor layer of the second transistor to the substrate is within a projection range of the first gate and the second gate to the substrate, and a projection range of a semiconductor layer of the third transistor and a semiconductor layer of the fourth transistor to the substrate is within a projection range of the third gate and the fourth gate to the substrate.

Other novel features of the disclosure will become more apparent from the following detailed description when taken in conjunction with the accompanying drawings.

### BRIEF DESCRIPTION OF DRAWINGS

FIG. 1 is a schematic structural diagram of the electronic device of the present disclosure;

FIG. 2A is a schematic diagram of a circuit unit of the electronic device according to the present disclosure;

FIG. 2B is a schematic diagram of another circuit unit of the electronic device according to the present disclosure;

FIG. 3A schematically illustrates the layout of a switching element of the electronic device according to an embodiment of the present disclosure;

FIG. 3B shows a schematic diagram of the structure of the switching element and the corresponding circuit diagram based on the cross-sectional view taken along line A-A′ of the layout of the switching element shown in FIG. 3A;

FIG. 4A schematically illustrates the layout of a switching element of the electronic device according to another embodiment of the present disclosure;

FIG. 4B schematically illustrates the structure of the switching element based on the cross-sectional view taken along line A-A′ of the layout of the switching element in FIG. 4A;

FIG. 5 is a schematic diagram of the layout of a switching element of the electronic device according to still another embodiment of the present disclosure; and

FIG. 6 is a schematic diagram of the layout of a switching element of the electronic device according to yet another embodiment of the present disclosure.

### DETAILED DESCRIPTION OF EMBODIMENT

The implementation of the present disclosure is illustrated by specific embodiments to enable persons skilled in the art to easily understand the other advantages and effects of the present disclosure by referring to the disclosure contained therein. The present disclosure is implemented or applied by other different, specific embodiments. Various modifications and changes can be made in accordance with different viewpoints and applications to details disclosed herein without departing from the spirit of the present disclosure.

Ordinal numbers, such as “first” and “second”, used herein are intended to distinguish components rather than disclose explicitly or implicitly that names of the components bear the wording of the ordinal numbers. The ordinal numbers do not imply what order a component and another component are in terms of space, time or steps of a manufacturing method. The ordinal numbers are only intended to distinguish a component with a name from another component with the same name.

It should be noted that, in the specification and claims, unless otherwise specified, having “one” element is not limited to having a single said element, but one or more said elements may be provided. In addition, in the specification and claims, unless otherwise specified, ordinal numbers, such as “first” and “second”, used herein are intended to distinguish components rather than disclose explicitly or implicitly that names of the components bear the wording of the ordinal numbers. The ordinal numbers do not imply what order a component and another component are in terms of space, time or steps of a manufacturing method. A “first” element and a “second” element may appear together in the same component, or separately in different components. The existence of an element with a larger ordinal number does not necessarily mean the existence of another element with a smaller ordinal number.

In the entire specification and appended claims of the present disclosure, certain words are used to refer to specific components. Those skilled in the art should understand that electronic device manufacturers may refer to the same components by different names. The present disclosure does not intend to distinguish those components with the same function but different names. In the following description and claims, words such as “comprising”, “including”, and “having” are open type words, so they should be interpreted as meaning “including but not limited to”. Therefore, when the terms “comprising”, “including” and/or “having” are used in the description of the present disclosure, they specify the existence of corresponding features, regions, steps, operations and/or components, but do not exclude the existence of one or more corresponding features, regions, steps, operations and/or components.

In the description, the terms “almost”, “about”, “approximately” or “substantially” usually means within 10%, 5%, 3%, 2%, 1% or 0.5% of a given value or range. The quantity given here is an approximate quantity; that is, without specifying “almost”, “about”, “approximately” or “substantially”, it can still imply the meaning of “almost”, “about”, “approximately” or “substantially”. In addition, the term “range of the first value to the second value” or “range between the first value and the second value” indicates that the range includes the first value, the second value, and other values between the first and second values.

Unless otherwise defined, all terms (including technical and scientific terms) used here have the same meanings as commonly understood by those skilled in the art of the present disclosure. It is understandable that these terms, such as those defined in commonly used dictionaries, should be interpreted as having a meaning consistent with the relevant technology and the background or context of the present disclosure, rather than in an idealized or excessively formal interpretation, unless specifically defined.

In addition, relative terms such as “below” or “bottom”, and “above” or “top” may be used in the embodiments to describe the relationship between one component and another component in the drawing. It can be understood that, if the device in the drawing is turned upside down, the components described on the “lower” side will become the components on the “upper” side. When the corresponding member (such as a film or region) is described as “on another member”, it may be directly on the other member, or there may be other members between the two members. On the other hand, when a member is described as “directly on another member”, there is no member between the two members. In addition, when a member is described as “on another member”, the two members have a vertical relationship in the top view direction, and this member may be above or below the other member, while the vertical relationship depends on the orientation of the device.

In the present disclosure, the distance, length, width, thickness and depth can be measured by using an optical microscope, and the distance, length, width, thickness and depth can be measured by the cross-sectional image in an electron microscope, but it is not limited thereto. In addition, there may be a certain error in any two values or directions used for comparison. If the first value is equal to the second value, it implies that there may be an error of about 10% between the first value and the second value. If the first direction is perpendicular to the second direction, the angle between the first direction and the second direction may be 80 to 100 degrees. If the first direction is parallel to the second direction, the angle between the first direction and the second direction may be 0 to 10 degrees.

It should be noted that the technical solutions provided by the different embodiments described hereinafter may be used interchangeably, combined or mixed to form another embodiment without violating the spirit of the present disclosure.

The electronic device of the present disclosure may include, for example, a display device, a sensing device, an antenna device, a touch device, a tiled device or other suitable electronic devices, but not limited thereto. The display device of the present disclosure may be a non-self-luminous display device or a self-luminous display device, such as a liquid crystal display, a cholesteric liquid crystal display, an electro-phoretic display, an organic light-emitting diode display, a light-emitting diode display, but not limited thereto. The display device may include a light emitting diode, a light transformation layer or other suitable materials, or a combination thereof, but not limited thereto. The light-emitting diode may include, for example, an organic light-emitting diode (OLED), a sub-millimeter light-emitting diode (mini LED), a micro light-emitting diode (micro LED) or a quantum dot light-emitting diode (quantum dot LED, which may include QLED, QDLED), but not limited thereto. The light transformation layer may include wavelength transformation materials and/or filter materials. The light transformation layer may include, for example, fluorescence, phosphor, quantum dot (QD), other suitable materials or a combination thereof, but not limited thereto. The sensing device may include, for example, a biosensor, a touch sensor, a fingerprint sensor, other suitable sensors, or a combination thereof. The antenna device may be, for example, a liquid crystal antenna or other types of antennas, but not limited thereto. The tiled device may include, for example, a tiled display device or a tiled antenna device, but not limited thereto. The electronic device may include electronic components, and the electronic components may include passive components, active components, or a combination thereof, such as capacitors, resistors, inductors, varactor diodes, variable capacitors, filters, diodes, transistors, sensors, micro-electro-mechanical system components (MEMS), chips, etc., but e not limited thereto. It should be noted that the electronic device of the present disclosure may be various combinations of the above devices, but not limited thereto.

It should be noted that the technical solutions provided by the different embodiments described hereinafter may be used interchangeably, combined or mixed to form another embodiment without violating the spirit of the present disclosure.

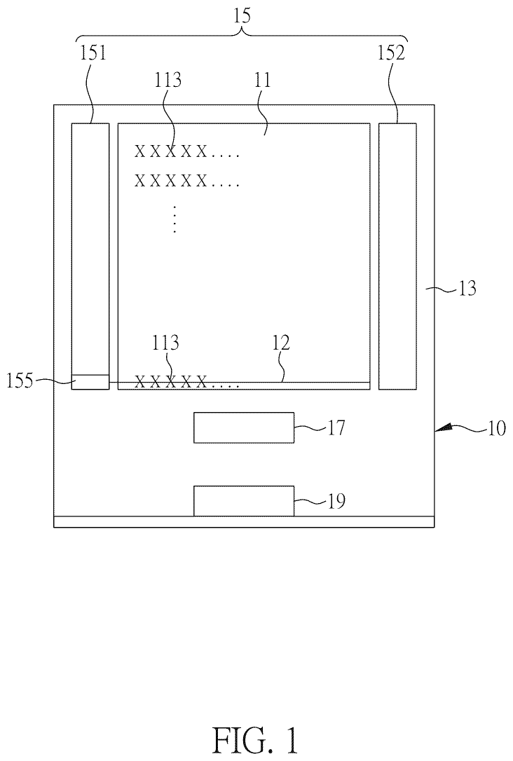

Please refer to FIG. 1, which is a schematic structural diagram of the electronic device 1 of the present disclosure, wherein the electronic device 1 is exemplified by a display device. The electronic device 1 has a substrate 10. The substrate 10 includes an active area 11 and a peripheral circuit area 13, and the active area 11 may be, for example, a display area, a detection area, a light emitting area, a touch area, or a combination of the above, but it is not limited thereto. In some embodiments, multiple pixel circuits 113 are formed in the active area 11 for displaying images. The area outside the active area 11 of the substrate 10 is the peripheral circuit area 13. The peripheral circuit area 13 has a gate driving element 15, an electronic element 17 (such as a driver chip, but not limited thereto) and/or a circuit board 19 (such as a flexible circuit board or a rigid circuit board). The electronic element 17 is used to control the operation of the gate driving element 15. The circuit board 19 may be used to connect external circuits and transmit signals to the gate driving element 15. FIG. 1 shows that the gate driving element 15 includes a first gate driving element 151 and a second gate driving element 152 respectively disposed on both sides of the active area 11 to drive the pixel circuits 113 in the active area 11 from both sides of the active area 11, while this is only an example but not a limitation. The gate driving element 15 may also only include a gate driving element disposed on a single side of the active area 11, and use the gate driving element to drive the pixel circuits 113 in the active area 11. The gate driving element 15 may be, for example, a gate driving element in the form of GOP (Gate On Panel) fabricated on the panel, but it is not limited thereto.

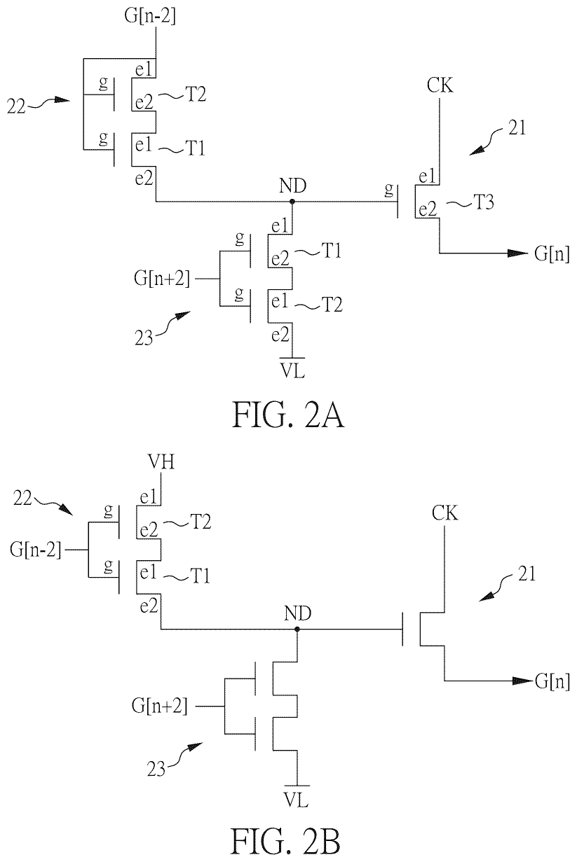

As shown in FIG. 1, the gate driving element 15 has at least one circuit unit 155. FIG. 2A is a schematic diagram of a circuit unit of the electronic device according to the present disclosure. The circuit unit 155 includes, for example, a switching element 21, a switching element 22 and/or a switching element 23, and the switching element 21, the switching element 22 and/or the switching element 23 may be, for example, disposed in the peripheral circuit area 13. The above circuit structure of the circuit unit 155 is only for illustrative purpose, and other switching elements or other circuit structures (such as capacitors, etc.) may be added as required. In the embodiment of the present disclosure, in order to reduce the leakage current of the switching element (such as the switching element 22 and/or the switching element 23) when it is turned off, the switching element 22 and/or the switching element 23, for example, may adopt a dual-gate structure, but it is not limited thereto. As shown, the switching element 22 includes a first transistor T1 and a second transistor T2, the switching element 23 includes a first transistor T1 and a second transistor T2, and the switching element 21 includes a transistor T3, but it is not limited thereto. In this embodiment, the transistors in the switching element 22, the switching element 23 or the switching element 21 are, for example, NMOS transistors, but it is not limited thereto. In other embodiments (not shown), the transistors in the switching element 22, the switching element 23 or the switching element 21 may also be PMOS transistors or other suitable types of transistors.

The first transistor T1 of the switching element 22 has a first end e1, a second end e2 and a gate g, wherein the first end e1 may be one of the drain and source, and the second end e2 may be the other end of the drain and the source. In this embodiment, for example, the first end e1 and the second end e2 of the first transistor T1 are the drain and the source, respectively. The second transistor T2 of the switching element 22 has a first end e1, a second end e2 and a gate g, wherein the first end e1 may be one of the drain and source, and the second end e2 may be the other one of the drain and source. In this embodiment, for example, the first end e1 and the second end e2 of the second transistor T2 are the drain and the source, respectively. Furthermore, the first end e1 of the first transistor T1 is connected to the second end e2 of the second transistor T2, the gate g of the first transistor T1 is connected to the gate g of the second transistor T2, and the gate g of the first transistor T1 and the gate g of the second transistor T2 may be further connected to the first end e1 of the second transistor T2, so as to form the switching element 22 with a dual-gate structure, but it is not limited thereto. The first transistor T1 of the switching element 23 has a first end e1, a second end e2 and a gate g, wherein the first end e1 may be one of the drain and source, and the second end e2 may be the other one of the drain and source. In this embodiment, for example, the first end e1 and the second end e2 of the first transistor T1 are the drain and the source, respectively, but it is not limited thereto.

The second transistor T2 of the switching element 23 has a first end e1, a second end e2 and a gate g, wherein the first end e1 may be one of the drain and source, and the second end e2 may be the other one of the drain and source. In this embodiment, for example, the first end e1 and the second end e2 of the second transistor T2 of the switching element 23 are the drain and the source, respectively. Furthermore, the second end e2 of the first transistor T1 of the switching element 23 is connected to the first end e1 of the second transistor T2, and the gate g of the first transistor T1 is connected to the gate g of the second transistor T2, so as to form a switching element 23 with a dual-gate structure, but it is not limited thereto. In addition, the transistor T3 of the switching element 21 has a first end e1, a second end e2 and a gate g.

The first end e1 of the second transistor T2 of the switching element 22 is connected to a scan line 12, for example, the (n−2)-th scan line G[n−2] as marked in FIG. 2A. One end of the switching element 22 serving as the source or drain (that is, the second end e2 of the first transistor T1 of the switching element 22), one end of the switching element 23 serving as the source or drain (that is, the first end e1 of the first transistor T1 of the switching element 23) and/or the gate g of the transistor T3 of the switching element 21 are connected to a node ND, the second end e2 of the second transistor T2 of the switching element 23 is connected to a voltage level VL (for example, (low voltage, but not limited thereto), the gate g of the first transistor T2 and the gate g of the second transistor T2 of the switching element 23 are connected to a scan line 12, for example, the (n+2)-th scan line G[n+2] as marked in FIG. 2A, but it is not limited thereto. In other embodiments (not shown), the first end e1 of the second transistor T2 of the switching element 22 is connected to a scan line 12, for example, the (n−X)-th scan line G[n−X], and the gate g of the first transistor T2 and the gate g of the second transistor T2 of the switching element 23 are connected to a scan line 12, for example, the (n+X)-th scan line G[n+X], where X may be any positive integer. The first end e1 of the transistor T3 of the switching element 21 is connected to a clock signal CK, and the second end e2 of the transistor T3 of the switching element 21 is connected to a scan line 12, for example, the n-th scan line G[n] as marked in FIG. 2A, but it is not limited thereto.

With the structure and connection of the circuit unit 155, it is able to drive the pixel circuit 113 on the scan line G[n]. During driving, when the node ND is at a voltage level VH (such as a high voltage, but not limited thereto) and the switching element 22 and the switching element 23 are turned off, for example, since the switching element 22 and the switching element 23 both have the dual-gate structure, the leakage current of the switching element 22 and the switching element 23 when turned off can be effectively reduced, so that the switching element 21 may operate normally.

FIG. 2B is a schematic diagram of another circuit unit of the electronic device according to the present disclosure, which is similar to the circuit unit 155 of FIG. 2A, except that the gate g of the first transistor T1 connected with the gate g of the second transistor T2 of the switching element 22 is not further connected to the first end e1 of the second transistor T2, but is connected to a scan line 12, for example, the (n−2)-th scan line G[n−2] as marked in FIG. 2B, and the first end e1 of the second transistor T2 of the switching element 22 is connected to the voltage level VH, for example, but it is not limited thereto. Since the circuit elements of the circuit unit 155 of FIG. 2A and FIG. 2B are the same, and the aforementioned description of the circuit unit 155 of FIG. 2A may also be applicable to the circuit unit 155 of FIG. 2B, a detailed description for the circuit unit 155 of FIG. 2B is thus deemed unnecessary. In other embodiments (not shown), the (n−2)-the scan line G[n−2] in FIG. 2B may be modified to the (n−X)-th scan line G[n−X], and the (n+2)-th scan line G[n+2] in FIG. 2B may be modified to the (n+X)-th scan line G[n+X], for example, where X may be any positive integer.

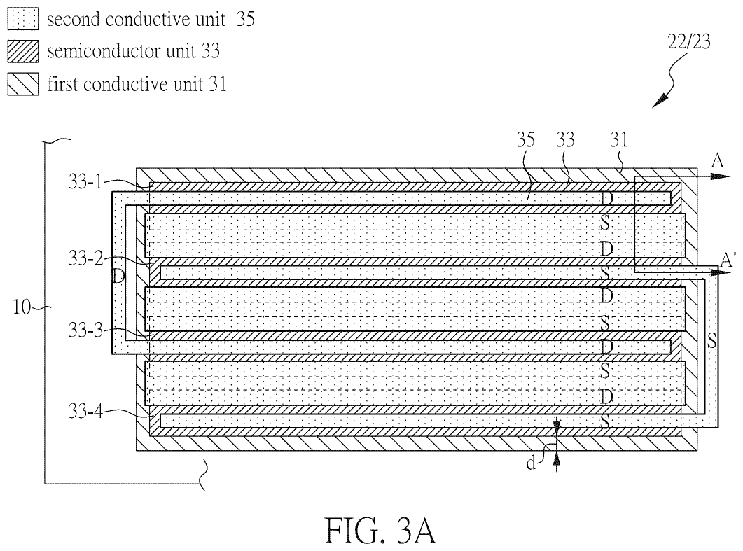

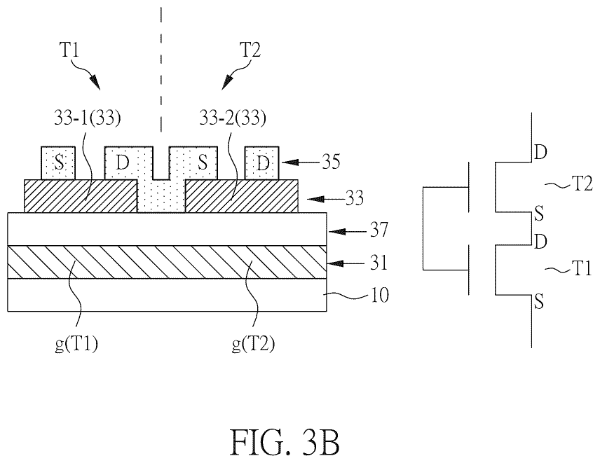

The space occupied by the double-gate structure of the aforementioned switching element 22 or 23 may be further reduced through the layout design. FIG. 3A schematically illustrates the layout of a switching element of the electronic device according to an embodiment of the present disclosure, wherein the switching element shown in FIG. 3A is a switching element 22 or 23 with a dual-gate structure, and the switching element 22 or 23 is formed by a gate layer, a semiconductor layer and an electrode layer respectively through layout design, that is, each of the switching element 22 and the switching element 23 includes a first conductive unit 31 (gate layer), a semiconductor unit 33 (semiconductor layer) and a second conductive unit 35 (electrode layer), wherein the first conductive unit 31 of the switching element 22 or 23 includes the gate g of the first transistor T1 and the gate g of the second transistor T2. As shown in FIG. 3B, the first conductive unit 31, the semiconductor unit 33 and the second conductive unit 35 are disposed sequentially on the substrate 10, and the second conductive unit 35 at least includes a drain D and a source S, but it is not limited thereto. In other words, the first transistor T1 includes a drain D and a source S, in which the first gate g (refer to a portion of the first conductive unit 31), the semiconductor layer 33-1 of the first transistor T1 and the drain D of the first transistor T1 (refer to a portion of the second conductive unit 35) are sequentially disposed on the substrate 10.

The projection range of the semiconductor unit 33 to the substrate 10 is located within the projection range of the first conductive unit 31 to the substrate 10. In other words, as shown in FIG. 3A and FIG. 3B, the projection range of the semiconductor layer 33-1 of the first transistor T1 and the semiconductor layer 33-2 of the second transistor T2 to the substrate 10 (please refer to the projection range of the semiconductor unit 33 to the substrate 10) is located within the projection range of the first gate g and the second gate g to the substrate 10 (please refer to the projection range of the first conductive unit 31 to the substrate 10). In one embodiment, the distance d between at least one edge of the first conductive unit 31 and the edge of the semiconductor unit 33 adjacent thereto is greater than 0 and less than or equal to 10 micrometers (0<d<=10 μm). In one embodiment, the distance d between at least one edge of the first conductive unit 31 and the edge of the semiconductor unit 33 adjacent thereto is greater than 0 and less than or equal to 8 μm (0<d<=8 μm). In one embodiment, the distance d between at least one edge of the first conductive unit 31 and the edge of the semiconductor unit 33 adjacent thereto is greater than 0 and less than or equal to 6 micrometers (0<d<=6 μm). In one embodiment, the distance d between at least one edge of the first conductive unit 31 and the edge of the semiconductor unit 33 adjacent thereto is greater than 0 and less than or equal to 4 μm (0<d<=4 μm). The first conductive unit 31 includes, for example, the gate g of the transistor T1 of the switching element 22 or the switching element 23 and the gate g of the transistor T2. The semiconductor unit 33 includes the semiconductor layer 33-1 of the transistor T1 and the semiconductor layer 33-2 of the transistor T2. In some embodiments, the semiconductor unit 33 is, for example, divided into multiple blocks and thus includes multiple semiconductor portions (as shown in FIG. 3A, for example but not limited thereto, divided into a semiconductor portion 33-1, a semiconductor portion 33-2, a semiconductor portion 33-3 and/or a semiconductor portion 33-4) for serving as channels of the transistor T1 and the transistor T2. The second conductive unit 35 includes the sources S and the drains D of the transistor T1 and the transistor T2. With reference to FIG. 3B, the semiconductor layer 33-1 of the transistor T1 and the semiconductor layer 33-2 of the transistor T2 may be separated from each other, for example. In this embodiment, the dimensions (for example, length or width) of the multiple semiconductor portions (for example, semiconductor layer 33-1 and semiconductor layer 33-2) may be the same or different from each other. The multiple semiconductor portions are arranged sequentially in at least one direction, for example. The multiple semiconductor portions (semiconductor portion 33-1, semiconductor portion 33-2, semiconductor portion 33-3 and/or semiconductor portion 33-4) are exemplified by rectangular shapes, but it is not limited thereto. The shape of the multiple semiconductor portions may be adjusted according to needs. The drain D included in the second conductive unit 35 may be, for example, provided with multiple drain portions, respectively. One of the drain portions may include at least one turning portion, wherein the shape of the drain portion may be L-shaped, reverse U-shaped or U-shaped, but it is not limited thereto. The source S included in the second conductive unit 35 may be, for example, provided with multiple source portions, respectively. One of the source portions may include at least one turning portion, and the shape of one of the source portions may be L-shaped, reverse U-shaped or U-shaped, but it is not limited thereto. FIG. 3A illustrates that a reverse U-shaped drain portion and a U-shaped source portion are arranged staggered with each other, but it is not limited thereto.

FIG. 3B shows a schematic diagram of the structure of the switching element and the corresponding circuit diagram based on the cross-sectional view taken along line A-A′ of the layout of the switching element shown in FIG. 3A. As shown, the switching element 22 or 23 (or transistor) sequentially includes the first conductive unit 31, a gate insulation unit 37, the semiconductor unit 33 and the second conductive unit 35 from bottom to top, and the left side and right sides in the schematic diagram of structure of the switching element in FIG. 3B are respectively labeled as transistor T1 and transistor T2, while this is only for convenience of explanation but not limitation. The first conductive unit 31 includes the gate g of the transistor T1 and the gate g of the transistor T2 and, as shown in FIG. 3A, since the semiconductor unit 33 may be, for example, divided into multiple blocks, the semiconductor unit 33 may be divided into two separated portions for use as the semiconductor layer 33-1 of the transistor T1 and the semiconductor layer 33-2 of the transistor T2, respectively, but it is not limited thereto. The gate insulation unit 37 is, for example, disposed between the first conductive unit 31 and the semiconductor unit 33. The second conductive unit 35 is used, for example, as the sources D and the drains S of the transistor T1 and the transistor T2, wherein the drain D of the transistor T1 and the source S of the transistor T2 are, for example, connected together, and part of the second conductive unit 35 (that is, the connection portion between the drain D of the transistor T1 and the source S of the transistor T2, for example) is above and overlaps the gap between two portions of the adjacent semiconductor units 33 (that is, the semiconductor layer 33-1 and the semiconductor layer 33-2), so as to realize the circuit diagram of the switching element 22 or 23 shown in FIG. 3B. In other words, the first transistor T1 includes a drain D and a source S, in which the first gate g of the transistor T1, the semiconductor layer 33-1 of the transistor T1, and the drain D (or source S) of the transistor T1 are sequentially disposed on the substrate 10.

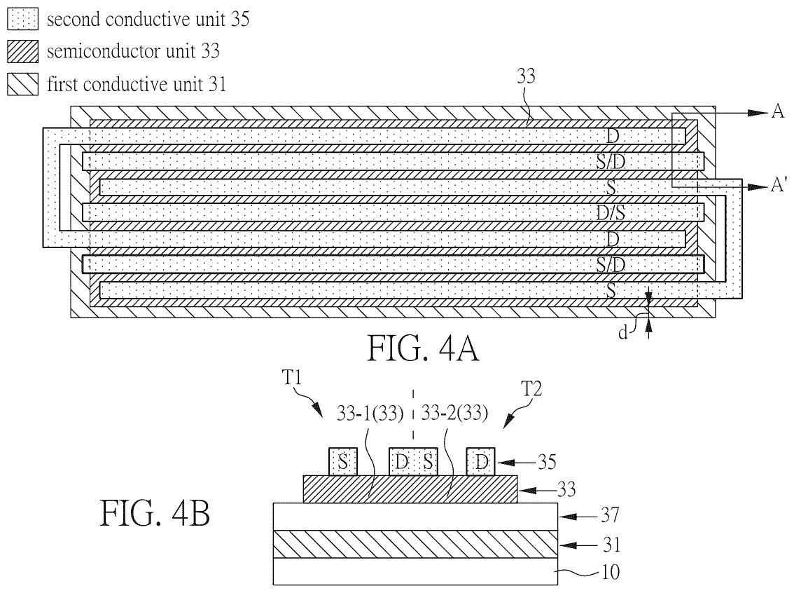

FIG. 4A is a schematic diagram of the layout of the switching element of an electronic device according to another embodiment of the present disclosure. This embodiment is similar to that of FIG. 3A, except that the semiconductor unit 33 is an integral single block but not being divided into multiple blocks. Therefore, the drains D and the sources S of the transistor T1 and the transistor T2 share the semiconductor unit 33, for example. In other words, the semiconductor layer 33-1 of the first transistor T1 and the semiconductor layer 33-2 of the second transistor T2 are connected to each other. As shown in FIG. 4A, the circuit layout marked as S/D or D/S is, for example, the portion of the second conductive unit 35 (that is, the connection of the source S of the transistor T1 and the drain D of the transistor T2, or the connection of the drain D of the transistor T1 and source S of the transistor T2). Furthermore, as shown in FIG. 4B that schematically illustrates the structure of the switching element based on the cross-sectional view taken along line A-A′ of the layout of the switching element in FIG. 4A, it also shows that the drain D of the transistor T1 and the source S of the transistor T2 share the semiconductor unit 33. Since the above description of the embodiment of FIG. 3A and FIG. 3B may be applicable to this embodiment, a detailed description for the switching element of FIG. 4A and FIG. 4B is deemed unnecessary. In addition, compared with the embodiment of FIG. 3A, since the drains D and sources S of the transistor T1 and the transistor T2 in this embodiment may share the semiconductor unit 33, the layout pattern is simple and the layout space can be further reduced. The circuit layout is shown in FIG. 4A. As mentioned above, the second conductive unit 35 includes a drain D and a source S. The drain D may be divided into multiple drain portions, and one of the drain portions includes, for example, at least one turning portion, wherein the shape of one of the drain portions may be, for example, L-shaped, reverse U-shaped, or U-shaped, For example, the source S may be divided into multiple source portions. One of the source portions includes at least one turning portion. The shape of the source portion is, for example, L-shaped, reverse U-shaped, or U-shaped, but it is not limited thereto. FIG. 3A or FIG. 4A is exemplified by a reverse U-shaped drain portion and a U-shaped source portion arranged staggered with each other, but it is not limited thereto. Similar to the above, in one embodiment, the distance d between at least one edge of the first conductive unit 31 and the edge of the semiconductor unit 33 adjacent thereto is greater than 0 and less than or equal to 10 micrometers (0<d<=10 μm), but it is not limited thereto. In one embodiment, the distance d between at least one edge of the first conductive unit 31 and the edge of the semiconductor unit 33 adjacent thereto is greater than 0 and less than or equal to 8 micrometers (0<d<=8 μm), but it is not limited thereto. In one embodiment, the distance d between at least one edge of the first conductive unit 31 and the edge of the semiconductor unit 33 adjacent thereto is greater than 0 and less than or equal to 6 micrometers (0<d<=6 μm), but it is not limited thereto.

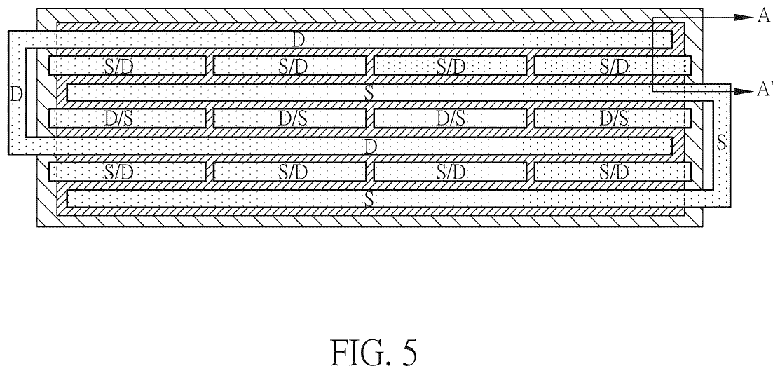

FIG. 5 is a schematic diagram of the layout of the switching element of an electronic device according to still another embodiment of the present disclosure. This embodiment is similar to the embodiment of FIG. 4A, except that the portion of the second conductive unit 35 (marked as S/D or D/S) is further divided into multiple segments that are arranged sequentially along one direction, for example. Accordingly, the schematic diagram of the switching element structure obtained based on the cross-sectional view taken along line AA′ of the layout of the switching element in FIG. 5 is the same as that in FIG. 4B. Moreover, the aforementioned description of the embodiment of FIG. 4A and FIG. 4B may also be applicable to this embodiment, and thus a detailed description for the switching element of FIG. 5 is deemed unnecessary. The dimensions (for example, length or width) of the multiple segments of the second conductive unit 35 may be the same as or different from each other. The multiple segments of the second conductive unit 35 (for example, the connection of the source S and the drain D) is, for example, rectangular, but it is not limited thereto. The shape of the segment of the second conductive unit 35 may be modified according to requirements.

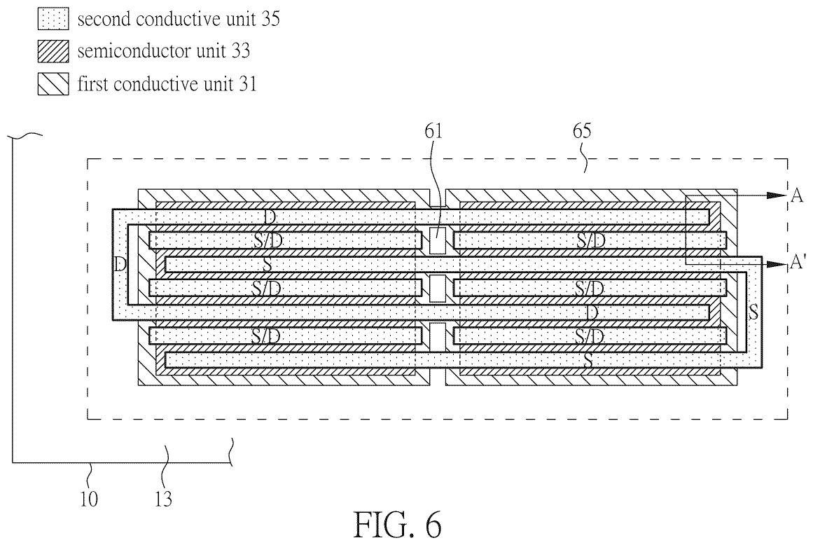

FIG. 6 is a schematic diagram of the layout of the switching element of an electronic device according to yet another embodiment of the present disclosure. This embodiment is similar to that of FIG. 4A, except that the electronic device further includes a seal 65 disposed on the substrate 10 and disposed in the peripheral circuit area 13. In the top view direction of the electronic device, the seal 65 overlaps at least part of the switch element, for example. In addition, the first conductive unit 31 is, for example, patterned so that the first conductive unit 31 includes at least one opening 61. In other words, the gate pattern formed by the first gate g of the transistor T1 and the second gate g of the transistor T2 (that is, the patterned first conductive unit 31) includes at least one opening 61. FIG. 6 illustrates that the gate pattern (that is, the patterned first conductive unit 31) includes multiple openings 61. The semiconductor unit 33 and/or the second conductive unit 35 above the opening 61 is, for example, designed to move away from the range of the opening 61. Therefore, in the top view direction of the electronic device, the opening 61 does not overlap the semiconductor unit 33 and/or the second conductive unit 35. In other words, in the top view direction of the electronic device, at least one opening 61 does not overlap the semiconductor layer 33-1 of the transistor T1 (for example, a portion of the semiconductor unit 33) and the semiconductor layer 33-2 of the transistor T2 (for example, a portion of the semiconductor unit 33). In other words, the transistor T1 and the transistor T2 respectively include a drain D (a portion of the second conductive unit 35) and a source S (a portion of the second conductive unit 35). In the top view direction of the electronic device, at least one opening 61 does not overlap the drain D of the transistor T1, the source S of the transistor T1, the drain D of the transistor T2, and the source S of the transistor T2. In the top view direction of the electronic device, the seal 65 overlaps at least one opening 61, for example. Accordingly, when manufacturing the electronic device, the light source (for example, ultraviolet light (UV)) may be used to cure the seal 65 through the opening 61. In addition, the schematic diagram of the structure of the switching element obtained based on the cross-sectional view taken along line AA′ of the layout of the switching element of FIG. 6 is the same as that of FIG. 4B, and the aforementioned description of the embodiment of FIG. 4A and FIG. 4B may also be applicable to this embodiment, and thus a detailed description for the switching element of FIG. 6 is deemed unnecessary.

According to the electronic devices of the various embodiments of the present disclosure, the switching element 22 and the switching element 23 both have, for example, a dual-gate structure, and thus, referring to the following Table 1, compared with the switching element of the prior single-gate structure, although the circuit layout area of the dual-gate structure is larger than that of the single-gate structure, the dual-gate structure of the present disclosure may effectively reduce the leakage current level on the switching element, so as to meet the actual needs. Furthermore, as shown in Table 1, compared with the first embodiment of the present disclosure (the embodiment of FIG. 3A), the second to fourth embodiments of the present disclosure (the embodiments of FIG. 4A, FIG. 5 and FIG. 6) may save the circuit layout space of the switching element through the layout design.

TABLE 1

| | | First | Second | Third | Fourth |
|---|---|---|---|---|---|
| | Single-gate | embodiment | embodiment | embodiment | embodiment |
| | (not shown) | (FIG. 3A) | (FIG. 4A) | (FIG. 5) | (FIG. 6) |
| Area | 100% | ~235% | ~157% | ~157% | ~165% |
| comparison for | | | | | |
| single-/dual-gate | | | | | |
| (%) | | | | | |
| Area | — | 100% | 67% | 67% | ~70% |
| comparison for | | | | | |
| dual-gate (%) | | | | | |

The details or features of the various embodiments of the present disclosure may be mixed and matched as long as they do not violate the spirit of the invention or conflict with each other.

The aforementioned specific embodiments should be construed as merely illustrative, and not limiting the rest of the present disclosure in any way.

1. An electronic device, comprising:
a substrate having a peripheral circuit area; and
a first switching element disposed in the peripheral circuit area and provided with a first transistor and a second transistor, wherein a first gate of the first transistor is connected to a second gate of the second transistor,
wherein a projection range of a semiconductor layer of the first transistor and a semiconductor layer of the second transistor to the substrate is within a projection range of the first gate electrode and the second gate electrode to the substrate.

2. The electronic device as claimed in claim 1, further comprising:
a second switching element disposed in the peripheral circuit area and provided with a gate connected to a node, a first end connected to a clock signal, and a second end connected to a scan line,
wherein a first end of the first switching element is connected to the node, and the first end is a source or a drain.

3. The electronic device as claimed in claim 1, wherein the first transistor includes a drain and a source, and wherein the first gate, the semiconductor layer of the first transistor and the drain of the first transistor are sequentially disposed on the substrate.

4. The electronic device as claimed in claim 1, wherein the semiconductor layer of the first transistor and the semiconductor layer of the second transistor are connected to each other.

5. The electronic device as claimed in claim 4, wherein the semiconductor layer of the first transistor and the semiconductor layer of the second transistor are separated from each other.

6. The electronic device as claimed in claim 1, wherein the first switching element includes a first conductive unit, a semiconductor unit and a second conductive unit sequentially disposed on the substrate, and wherein the first conductive unit includes the first gate of the first transistor and the second gate of the second transistor, the semiconductor unit includes the semiconductor layer of the first transistor and the semiconductor layer of the second transistor, and the second conductive unit includes drains and the sources of the first transistor and the second transistor.

7. The electronic device as claimed in claim 6, wherein the drain included in the second conductive unit is divided into multiple drain portions, and one of the drain portions includes at least one turning portion.

8. The electronic device as claimed in claim 7, wherein the source included in the second conductive unit is divided into multiple source portions, and one of the source portions includes at least one turning portion.

9. The electronic device as claimed in claim 6, wherein a distance between at least one edge of the first conductive unit and an edge of the semiconductor unit adjacent thereto is greater than 0 and less than or equal to 10 micrometers.

10. An electronic device, comprising:
a substrate having a peripheral circuit area; and
a first switching element disposed in the peripheral circuit area and provided with a first transistor and a second transistor, wherein a first gate of the first transistor is connected to a second gate of the second transistor, and wherein, in a top view direction of the electronic device, a gate pattern formed by the first gate and the second gate includes at least one opening, and the at least one opening does not overlap a semiconductor layer of the first transistor and a semiconductor layer of the second transistor.

11. The electronic device as claimed in claim 10, further comprising:
a second switching element disposed in the peripheral circuit area and provided with a gate connected to a node, a first end connected to a clock signal, and a second end connected to a scan line, wherein a first end of the first switching element is connected to the node, and the first end is a source or a drain.

12. The electronic device as claimed in claim 10, wherein each of the first transistor and the second transistor includes a drain and a source and, in a top view direction of the electronic device, the at least one opening does not overlap the drain of the first transistor, the source of the first transistor, the drain of the second transistor, and the source of the second transistor.

13. The electronic device as claimed in claim 10, further comprising a seal disposed on the substrate and located in the peripheral circuit area, wherein, in a top view direction of the electronic device, the seal overlaps the at least one opening.

14. The electronic device as claimed in claim 10, wherein the first transistor includes a drain and a source, and wherein the first gate, the semiconductor layer of the first transistor and the drain of the first transistor are sequentially disposed on the substrate.

15. The electronic device as claimed in claim 10, wherein the semiconductor layer of the first transistor and the semiconductor layer of the second transistor are connected to each other.

16. The electronic device as claimed in claim 10, wherein the first switching element includes a first conductive unit, a semiconductor unit and a second conductive unit sequentially disposed on the substrate, the first conductive unit includes the first gate of the first transistor and the second gate of the second transistor, the semiconductor unit includes the semiconductor layer of the first transistor and the semiconductor layer of the second transistor, the second conductive unit includes drains and sources of the first transistor and the second transistor, and the first conductive unit is patterned so that the first conductive unit includes the at least one opening.

17. An electronic device, comprising:
a substrate having a peripheral circuit area; and
a first switching element disposed in the peripheral circuit area and provided with a first transistor and a second transistor, wherein a first gate of the first transistor is connected to a second gate of the second transistor;
a second switching element disposed in the peripheral circuit area and provided with a third transistor and a fourth transistor, wherein a third gate of the third transistor is connected to a fourth gate of the fourth transistor,
wherein a first end of the first switching element and a first end of the second switching element are connected to a node, a projection range of a semiconductor layer of the first transistor and a semiconductor layer of the second transistor to the substrate is within a projection range of the first gate and the second gate to the substrate, and a projection range of a semiconductor layer of the third transistor and a semiconductor layer of the fourth transistor to the substrate is within a projection range of the third gate and the fourth gate to the substrate.

18. The electronic device as claimed in claim 17, further comprising:
a third switching element disposed in the peripheral circuit area and provided with a gate connected to the node, a first end connected to a clock signal, and a second end connected to a scan line.

19. The electronic device as claimed in claim 17, wherein a first end of the second transistor is connected to a scan line, the first gate and the second gate are connected together and then connected to a first end of the second transistor, and the third gate and the fourth gate are connected together and then connected to a scan line.

20. The electronic device as claimed in claim 17, wherein a first end of the second transistor is connected to a voltage level, the first gate and the second gate are connected together and then connected to a scan line, and the third gate and the fourth gate are connected together and then connected to a scan line.
